(19) United States
(12) Patent Application Publication
(10) Pub. No.: US 2013/0151185 A1
(43) Pub. Date: Jun. 13, 2013

(54) SEMICONDUCTOR DEVICE

(71) Applicant: Fujitsu Limited, Kawasaki-shi (JP)

(72) Inventor: Teruaki Yagoshi, Kawasaki (JP)

(73) Assignee: FUJITSU LIMITED, Kawasaki-shi (JP)

(21) Appl. No.: 13/764,263

(22) Filed: Feb. 11, 2013

Related U.S. Application Data
(63) Continuation of application No. PCT/JP2010/064117, filed on Aug. 20, 2010.

(51) Int. Cl. G01R 35/00; G06F 17/00

(52) U.S. Cl. CPC G01R 35/007; G06F 17/00
USPC 702/64; 702/58; 702/79

(57) ABSTRACT

A previously calibrated 01 alternating data signal from the driver of an output circuit is input to an input circuit. The voltage amplitude of the input signal is measured. The measured voltage amplitude is compared with the output amplitude of a driver, and an error is stored in a memory as a correction value. A phase and the amount of jitter are measured by using a clock with a specified phase and a specified amount of jitter. The measured phase and amount of jitter are compared with a specified phase and a specified amount of jitter, and an error is stored in a memory as a correction value. In a test, the amplitude and amount of jitter of an input signal from an alien IC are measured, and the measured amplitude and amount of jitter are corrected by a correction value stored in the memory.

### CROSS-REFERENCE TO RELATED APPLICATIONS

This application is a continuation application of International PCT Application No. PCT/JP2010/064117 which was filed on Aug. 20, 2010.

### FIELD

The embodiments discussed herein are related to a semiconductor device.

### BACKGROUND

Conventionally, the testing of high-speed I/Os at the shipping inspection stage of semiconductor devices is done by checking the operation with the testing of signal output, such as by using BIST (built-in self-test).

In the testing of signal output by using the conventional technique of a BIST function, even if a waveform that does not meet the standards is input due to a failure in I/O devices or cables, substrates, or the like, the LSI circuit performance (by a margin) may enable the LSI circuit to pass the signal output test. However, in such cases, the influence of an environmental change or the like after shipment on the input of a waveform that does not meet the standards as above may exceed the margin, and when it does, a malfunction occurs.

In order to prevent the above problem from occurring, the input/output signals are measured by using a measuring instrument, and whether the measured signals satisfy the standards is judged. However, a measuring apparatus capable of performing the input and output of clock signals and data of a few GHz is expensive. Moreover, when a number of tests are performed for such equipment as in the case of LSI circuits and the number of measuring apparatuses is insufficient, an enormous amount of time is required. Further, when several tests are performed at one time, a large number of measuring apparatuses are required and the cost tends to be enormous. Very low cost general measuring instruments have limitations, and may only be able to output a frequency of 100 MHz or less or a DC signal. Thus, there is a problem that such general measuring instruments are not capable of performing a test with signals of a few GHz.

Moreover, there is a problem that an enormous amount of money is needed for the development and manufacturing of a testing jig because the speed of signal transmission used for input and output of an LSI circuit is more than 1 Gbps. In view of this problem, the possibility of the integration of a test circuit inside an LSI circuit is considered in order to perform a test using signals of a few GHz. However, variations in characteristics will be caused when test circuits are manufactured due to voltage amplitude or constituent elements of a detector that detects the amount of jitter, and thus there is a problem that the characteristics of a detector will be different for each LSI circuit into which a test circuit is integrated.

As the speed of interfaces increases, attenuation of signal waveforms due to the effects of transmission lines or the like has become a problem. Accordingly, there are some cases in which just a check of signal output using a BIST (built-in self-test) does not satisfy a set point, or in which failure occurs due to an environmental change or the like because the lack of margin or the like is unknown.

When a test is performed for an LSI circuit by using signals of a few GHz, it is advantageous to form a test circuit inside the LSI. However, there will be variations in characteristics for each element of the test circuit that is formed inside the LSI circuit.

In the related art, a semiconductor device into which a test circuit is integrated for testing itself is available.

### PRIOR ART DOCUMENTS

### Patent Documents

[Patent Document 1] Japanese Laid-open Patent Publication No. 2002-057417

### SUMMARY

According to an aspect of the embodiments, a semiconductor device into which a testing device is integrated includes: a calibration unit integrated into the semiconductor device and configured to calibrate an element of the testing device; and a memory integrated into the semiconductor device and configured to store a correction value for a deviation from a reference value of a characteristic of the element obtained as a result of the calibration, wherein a result of a test performed by the testing device of the semiconductor device is corrected by the correction value stored in the memory to determine whether the corrected result meets standards.

In the embodiments described below, a semiconductor device is provided into which a testing device is integrated and that compensates for variations caused at each element of a test circuit. Accordingly, a test may be equally performed by any semiconductor device.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram of the entirety of an input amplitude detector, a phase detection circuit, and a test circuit for calibration according to the present embodiment.

FIG. 2 illustrates the calibration of a D/A converter (1).

FIG. 3 illustrates the calibration of a D/A converter (2).

FIGS. 4A and 4B illustrate the calibration of a D/A converter (3).

FIG. 5 illustrates the calibration of the output amplitude of a driver (1).

FIG. 6 illustrates the calibration of the output amplitude of a driver (2).

FIG. 7 illustrates the calibration of the output amplitude of a driver (3).

FIG. 8 illustrates the calibration of an input amplitude detector (1).

FIG. 9 illustrates the calibration of an input amplitude detector (2).

FIG. 10 illustrates the calibration of an input amplitude detector (3).

FIG. 11 illustrates the calibration of a phase detection circuit (1).

FIG. 12 illustrates the calibration of a phase detection circuit (2).

FIG. 13 illustrates the calibration of a phase detection circuit (3).

FIG. 14 illustrates the processes of detecting the amplitude values of the signals input from other drivers and performing a test for standard values or the like (1).

FIG. 15 illustrates the processes of detecting the amplitude values of the signals input from other drivers and performing a test for standard values or the like (2).

FIG. 16 illustrates the processes of detecting the amount of jitter of the signals input from other drivers and performing a test for standard values or the like (1).

FIG. 17 illustrates the processes of detecting the amount of jitter of the signals input from other drivers and performing a test for standard values or the like (2).

FIG. 18 illustrates the application of the present embodiment where the amount of crosstalk from an alien transmission line or several alien transmission lines is detected and judged according to a set point or the like (1).

FIG. 19 illustrates the application of the present embodiment where the amount of crosstalk from an alien transmission line or several alien transmission lines is detected and judged according to a set point or the like (2).

### DESCRIPTION OF EMBODIMENTS

In the present embodiment, a detector (or, a test circuit) is integrated into an LSI circuit having a high-speed I/O. By doing this, an amplitude value of the input to the LSI circuit or the amount of jitter maybe detected to judge whether the detected value satisfies a standard value (aimed value). The amplitude value is measured by using the output from the driver of an output circuit of the LSI circuit that is calibrated in advance. As the driver originally operates at the speed of a few GHz, the driver is capable of generating a 01 alternating signal of a few GHz. Accordingly, it becomes not necessary to prepare an oscillator of a few GHz as an external measuring instrument, and the cost of a testing device may be reduced.

In regard to an error of the detector due to individual variations, an error of element variations is compensated for by calibrating elements of the detector of a single LSI circuit and by storing a correction value in a memory.

The incorporation of an amplitude detector and a jitter amount detector inside an LSI circuit enables the measurement of an input amplitude value and an input jitter value used for determining whether the input signal satisfies a standard value. Moreover, a circuit that calibrates the detector is integrated into the LSI circuit, and the calibration result is stored in the memory. By so doing, an error in the detector is corrected, and an error in the detection result due to variations caused at each element is compensated for.

According to the present embodiment, an amplitude value or the amount of jitter may be detected even if a signal waveform that does not meet the standards is input, and it is possible to determine whether the input signal satisfies a standard value. There used to be a problem wherein a malfunction due to an environmental change was caused after the shipment by a device with no operational margin, but manufacturing defects maybe found if tested before the shipment. By doing this, advantageous effects of preventing a malfunction from occurring in the market are achieved.

If a test circuit is integrated into the LSI circuit, it becomes possible to configure a test circuit at low cost compared with when a testing jig is configured outside.

The present embodiment will be described below with reference to the accompanying drawings.

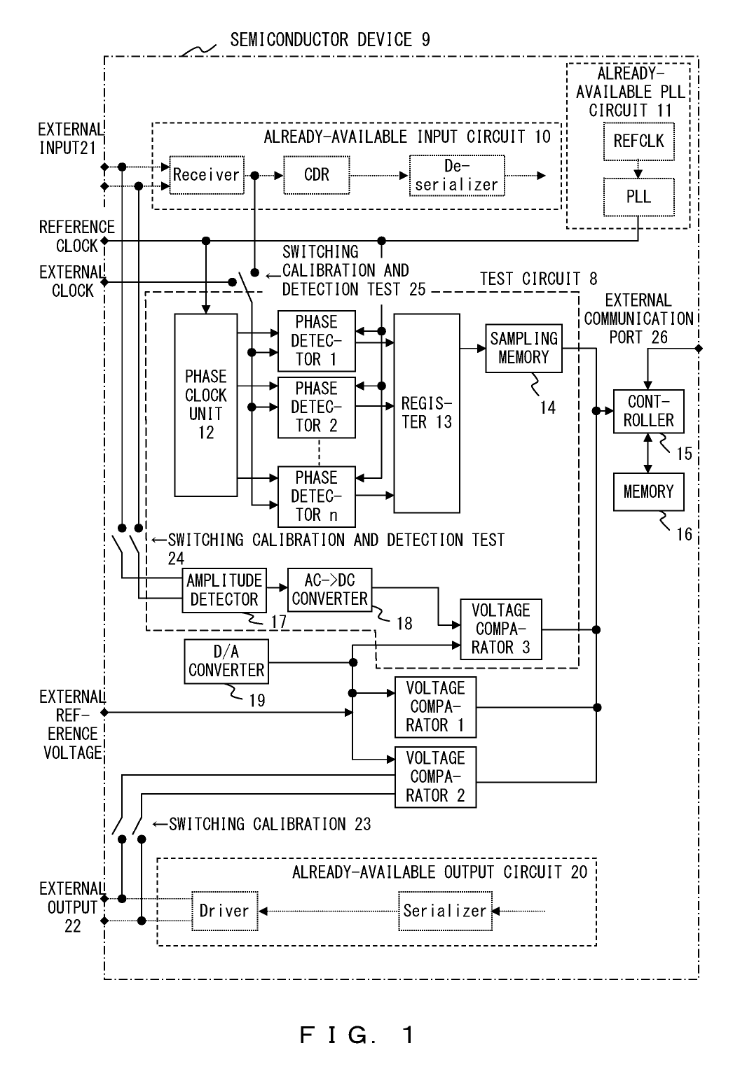

FIG. 1 is a block diagram of the entirety of an input amplitude detector, a phase detection circuit, and a test circuit for calibration according to the present embodiment.

A test circuit 8 is integrated into the semiconductor device 9. The test circuit 8 has an external input 21 and an external output 22. The external input 21 and the external output 22 meet the high-speed I/O specifications, and perform the input and output of signals of a few GHz. Moreover, the external input 21 and the external output 22 are differential input and output, and are provided with two signal lines. The external input 21 is connected to an already-available input circuit 10 that is used in normal operation. The already-available input circuit 10 includes a receiver, a CDR (Clock and Data Recovery), and a deserializer. The receiver is configured to receive an external input signal, and is provided with a terminating resistor. The CDR is configured to reconstitute clocks and data from the received signal, and the deserializer is configured to convert an input signal as a serial signal into a parallel signal.

An already-available PLL circuit 11 includes a reference clock and a PLL circuit, and provides a dynamic clock for the semiconductor device and outputs a clock signal (reference clock) to the outside in order to synchronize with an external circuit.

An already-available output circuit 20 is provided with a serializer and a driver. The serializer converts a parallel signal into a serial signal, and a driver converts a serial signal into a signal to be output to the outside. The driver generates and outputs signals of a few GHz through an external output 22. A switch 23 is turned ON when the driver of the already-available output circuit 20 is to be calibrated. Once the switch 23 is turned ON, the output of the driver of the already-available output circuit 20 is input to a voltage comparator 2 and its voltage is compared with the output of a D/A (Digital-Analog) converter 19. The comparison result is transferred to a controller 15.

A voltage comparator 1 compares the voltage between the output of the D/A converter 19 and an external reference voltage, and transfers the result to the controller 15.

Once a switch 24 is turned ON, the external input 21 to the already-available input circuit 10 is input to the amplitude detector 17. The amplitude detector 17 detects an amplitude value of the external input 21 and outputs the detected amplitude value to an AC-to-DC converter 18. The AC-to-DC converter 18 outputs to a voltage comparator 3 a signal in which the common voltage (core voltage) detected by the amplitude detector 17 is 0V to which a DC voltage is added such that a voltage at an “L” level will be a positive voltage. The voltage comparator 3 compares the voltage between a voltage value received from the AC-to-DC converter 18 with an output value from the D/A converter 19, and transfers the result to the controller 15.

The switch 25 switches between the calibration of the phase detectors 1 to n and the test of detecting the amount of jitter in the external input 21. In all cases, an input signal is input to the phase detectors 1 to n. A phase clock unit 12 generates phase clock signals from reference clocks, and the generated phase clock signals in which the amount of phase shift varies by a specified value and reference clocks are input to the phase detectors 1 to n. Then, the phase detectors 1 to n detect a matching result of phase between signals from the phase clock unit 12 and input signals. When there is a match, “1” is output to a register 13, and when there is no match, “0” is output to the register 13. The register 13 stores the result of one-time detection by the phase detectors 1 to n, and when all the results obtained by the phase detectors 1 to n are ready, the register 13 transfers the detection result to a sampling memory 14. The sampling memory 14 stores the results of multiple phase detections, and when the phase detection is completed, the sampling memory 14 transfers the result of the phase detection to the controller 15.

The controller 15 stores in the memory 16 a correction value obtained as a result of each calibration, and when a detection test is to be performed, the controller 15 holds a value of the result of a detection test that is corrected by a correction value stored in the memory 16. An external communication port 26 is used by an external test control computer (not illustrated) to input to the controller 15 a setpoint signal of a calibration mode, a device test mode, or a normal mode. The controller 15 performs the switching of switches 23, 24, and 25 as well as other forms of control according to the designated mode. Note that the results of a detection test held by the controller 15 maybe read by a computer that is connected to the external communication port for controlling the test or the like.

An input amplitude detector is provided with the amplitude detector 17, the AC-to-DC converter 18, and the voltage comparator 3, and a phase detection circuit is provided with the phase clock unit 12, the phase detectors 1 to n, the register 13, and the sampling memory 14. The input amplitude detector and the phase detection circuit are controlled by the controller 15.

Signal lines for such control, for example, a signal line from the controller 15 to the D/A converter 19, are omitted in FIG. 1, but they may be illustrated as necessary in the drawings described below. The test circuit 8 is provided with the input amplitude detector, the phase detection circuit, and the controller 15, and performs a test of an external input of the semiconductor device. A calibration unit includes the input amplitude detector and the phase detection circuit of the test circuit 8, and the controller 15, and further includes the D/A converter 19, and the voltage comparators 1 and 2.

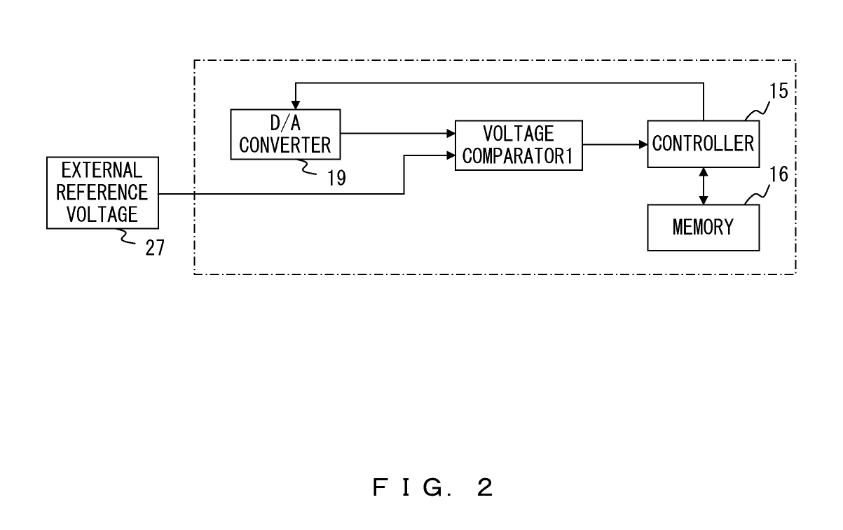

FIGS. 2 to 4 illustrate the calibration of a D/A converter.

Firstly, in order to perform the test of an LSI circuit, elements of a single unit of an LSI circuit are calibrated. An instruction to shift to the calibration mode is transmitted to the controller 15 via the external communication port 26. Once an instruction to shift to the calibration mode is received, the controller 15 sets up a register for the calibration mode, and calibrates a detector (input amplitude, input jitter).

FIG. 2 focuses on a circuit used to calibrate a D/A converter.

Firstly, a D/A converter is calibrated. The D/A converter is calibrated in order to calibrate a reference voltage for detecting a voltage value.

A reference voltage (DC voltage) 27 is externally set, and a reference voltage is input to the voltage comparator 1. Next, a voltage value of the D/A converter 19 is set by the control of the controller 15, and the set voltage is input to the voltage comparator 1. Then, the logic output from the voltage comparator 1 (i.e., a signal indicating the size of a voltage value, e.g., “1” when an external reference voltage is large and “0” when an external reference voltage is small) is discerned by the controller 15. When a voltage value of the D/A converter 19 is lower than a reference voltage, the level of the setting is increased by one step so as to increase the voltage output from the D/A converter 19, and the output from the voltage comparator 1 is discerned. This is repeated until the output from the voltage comparator 1 changes. In contrast, when a voltage value of the D/A converter 19 is higher than a reference voltage, the level of the setting is reduced by one step so as to reduce the voltage output from the D/A converter 19, and the output from the voltage comparator 1 is discerned again. This is repeated until the output from the voltage comparator 1 changes.

When the output from the voltage comparator 1 is changed, it is recorded in the memory 16 that the voltage output as a result of the setting of the D/A converter 19 at that time is equivalent to the voltage value of an external reference voltage. An external reference voltage is changed, and the above control is performed again (for example, control is performed for external reference voltages with three settings).

Accordingly, it becomes apparent how much voltage (mV) is changed in one setting of the D/A converter 19. If the amount that voltage (mV) is changed in one setting is known, when the voltage output from the D/A converter 19 is controlled later, it becomes possible to know how much voltage (mV) is increased by referring to the number of the settings with which the output is converted in stages.

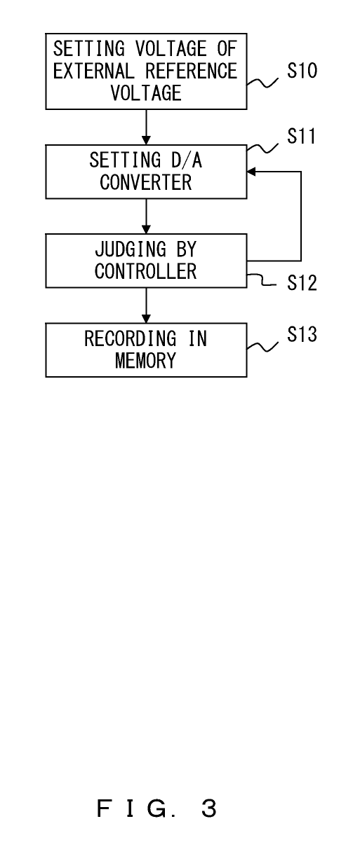

FIG. 3 is a flowchart illustrating the calibration performed by the D/A converter 19.

Firstly, the voltage value of an external reference voltage is set in step S10, and the voltage value of the D/A converter 19 is set in step S11. In step S12, the controller 15 determines which is larger between an external reference voltage and the voltage at the D/A converter 19. As described above, when the voltage at the D/A converter 19 is small, the level of the setting is increased by one step so as to increase the voltage at the D/A converter 19. When a voltage value of the D/A converter 19 is large, the level of the setting is reduced by one step so as to reduce the voltage at the D/A converter 19. The above process is repeated until the logic of the voltage comparator 1 changes. Then, in step S13, the set value of the voltage at the D/A converter 19 at the time when the logic of the voltage comparator 1 is changed is recorded in the memory 16.

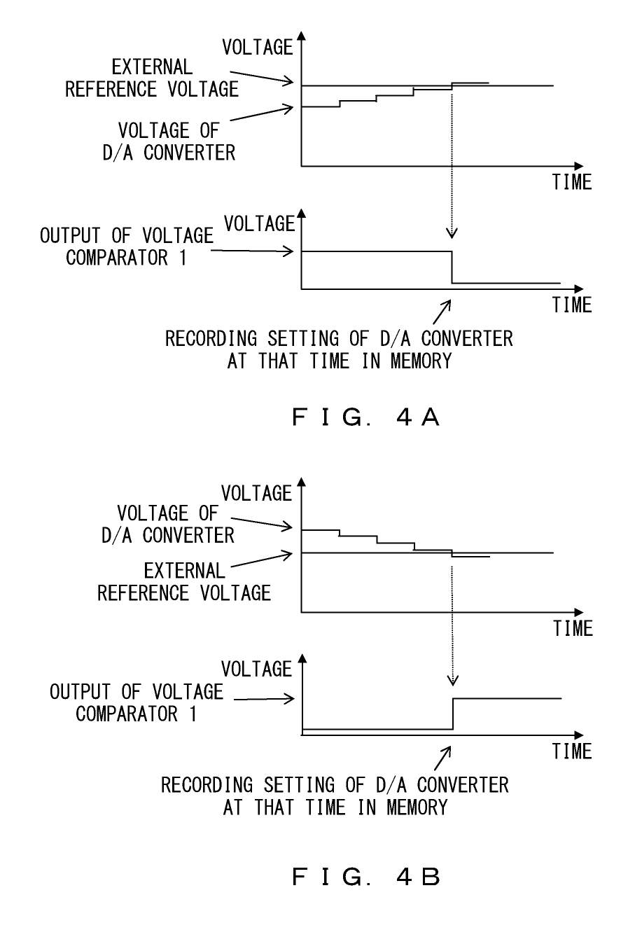

FIG. 4 illustrates how the set value of the voltage at the D/A converter 19 is set.

FIG. 4A illustrates the case in which an external reference voltage is greater than the voltage at the D/A converter 19, and FIG. 4B illustrates the case in which an external reference voltage is smaller than the voltage at the D/A converter 19.

As illustrated in FIG. 4A, when an external reference voltage is greater than the voltage at the D/A converter 19, the voltage output from the D/A converter 19 is gradually increased and the set value of the voltage at the D/A converter 19 at the time when the voltage at the D/A converter 19 has become greater than an external reference voltage is stored in the memory 16. The logic of the output from the voltage comparator 1 changes when the voltage at the D/A converter 19 becomes greater than an external reference voltage, and thus a change in the output from the voltage comparator 1 is monitored and the set value of the voltage at the D/A converter 19 is stored in the memory 16.

As illustrated in FIG. 4B, when an external reference voltage is smaller than the voltage at the D/A converter 19, the voltage output from the D/A converter 19 is gradually decreased and the set value of the voltage at the D/A converter 19 at the time when the voltage at the D/A converter 19 has become smaller than an external reference voltage is stored in the memory 16. The logic of the output from the voltage comparator 1 changes when the voltage at the D/A converter 19 becomes smaller than an external reference voltage, and thus a change in the output from the voltage comparator 1 is monitored and the set value of the voltage at the D/A converter 19 is stored in the memory 16.

For example, an external reference voltage is set to 400 mV, and the external reference voltage is input to the voltage comparator 1. Next, the setting of the D/A converter 19 is set to an estimated value of 350 mV, and the setting of the D/A converter 19 is input to the voltage comparator 1. The output of the voltage comparator is discerned by the controller 15, and when the output is “1”, the setting of the D/A converter 19 is set 10 mV larger than the previous setting and the output from the voltage comparator 1 is discerned by the controller 15. When “1” is obtained in the discernment, the setting of the D/A converter 19 is changed again. When “0” is obtained in the discernment, the estimated set value of the D/A converter was 360 mV but a voltage of 400 mV is actually being output. Accordingly, the fact that the voltage of 400 mV is output when the setting is 360 mV is stored in the memory 16.

Further, the cases in which an external reference voltage is set to 800 mV and 100 0mV will be described.

Note that when a difference between an external reference voltage and an estimated voltage value of the D/A converter 19 is greater than 100 mV, it is determined that the D/A converter 19 has failure and the calibration is terminated (i.e., the controller 15 sends an error notification to a test control computer through the external communication port).

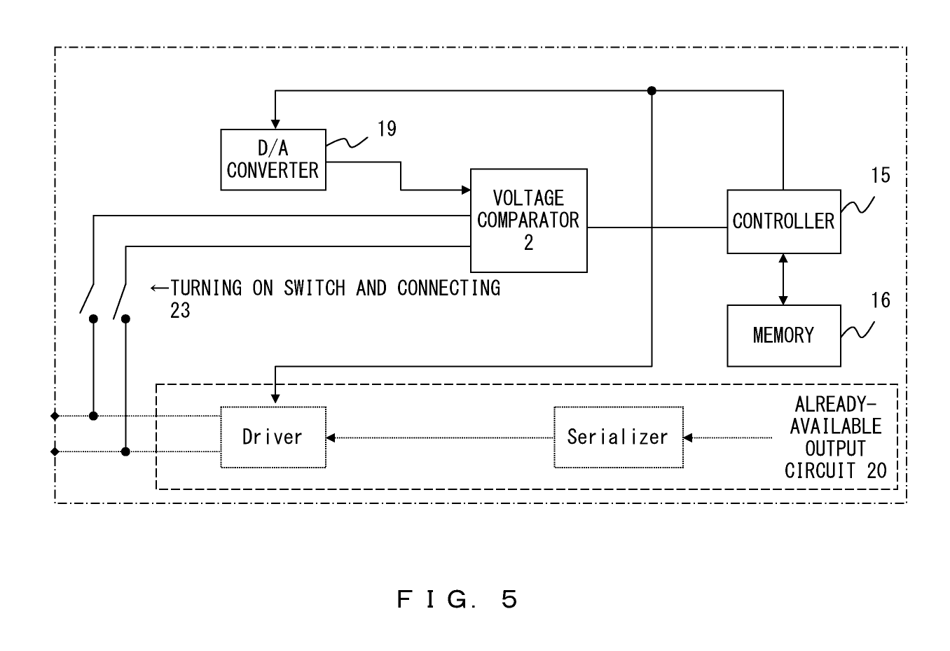

FIGS. 5 to 7 illustrates how the output amplitude of a driver is calibrated.

Here, the output voltage of the driver of the already-available output circuit 20 is calibrated.

In other words, calibration is performed by using a driver inside the LSI circuit such that output signals of a few GHz will be input to a receiver because it is difficult to externally input signals of a few GHz.

FIG. 5 focuses on a circuit used for calibrating the output amplitude of a driver.

Firstly, the driver amplitude is set and an “H” level (DC voltage) is output. Note that the voltage with the driver amplitude is a differential voltage. Next, the D/A converter 19 sets a transient voltage, and the transient voltage output is output. Here, the transient voltage is set by using a value obtained in the calibration of the D/A converter 19. Then, the logic output from the voltage comparator 2 (i.e., a signal indicating “1” when the voltage output from the driver is greater than the voltage at the D/A converter 19 and “0” when the voltage output from the driver is smaller than the voltage at the D/A converter 19) is discerned by the controller 15. When the voltage of the driver is high, the level of the setting is increased by one step so as to increase the voltage output from the D/A converter 19, and the output from the voltage comparator 2 is discerned by the controller. This is repeated until the output from the voltage comparator 2 changes. In contrast, when the voltage of the driver is low, the level of the setting is reduced by one step so as to reduce the voltage output from the D/A converter 19, and then the output from the voltage comparator 2 is discerned by the controller. This is repeated until the output from the voltage comparator 2 changes. When the output from the voltage comparator 2 is changed, a set value (voltage value) of the D/A converter 19 at that time is recorded in the memory 16.

Next, an “L” level (DC voltage) is output from the driver, and the “L” level is calibrated in a similar manner to the calibration of the “H” level.

As a result, a voltage value at the “H” level and a voltage value at the “L” level are measured, and the controller 15 calculates an amplitude value by using the measurement result and records the calculated value in the memory 16.

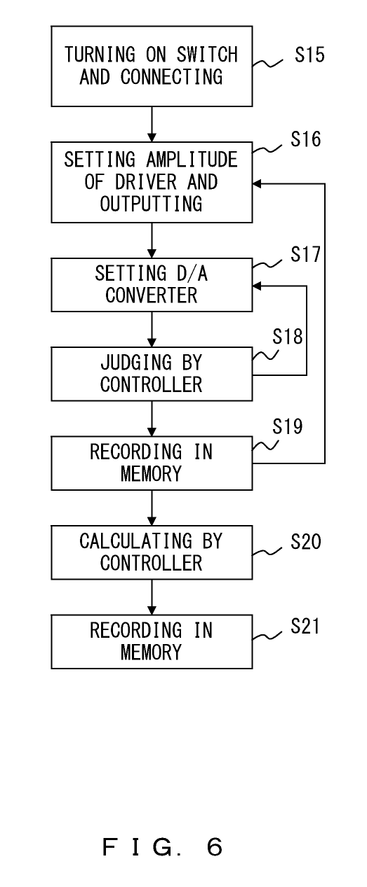

FIG. 6 is a flowchart illustrating the calibration of the output amplitude of a driver.

Firstly, in step S15, the controller 15 turns on the switch 23 according to the mode setting. In step S16, the amplitude value of the driver is set and the “H” level is output. In step S17, a transient value of the voltage output from the D/A converter 19 is set, and a transient voltage is output. Here, the transient voltage is set by using a value obtained in the calibration of the D/A converter 19. In step S18, the voltage comparator 2 compares the voltage of the driver with the voltage at the D/A converter 19, and judges a comparison result (step S18). When the voltage of the driver is larger than the voltage at the D/A converter 19, the level of the set value of the voltage at the D/A converter 19 is increased by one step, and the voltage at the D/A converter 19 is compared with the voltage of the driver again. The set value of the voltage at the D/A converter 19 is changed until the logic of the voltage comparator 2 is inverted, and the output from the D/A converter 2 at the time when the logic of the voltage comparator 2 is inverted is stored in the memory 16 in step S19. When the voltage of the driver is smaller than the voltage at the D/A converter 19, the level of the set value of the voltage at the D/A converter 19 is decreased by one step, and the voltage at the D/A converter 19 is compared with the voltage of the driver again. The set value of the voltage at the D/A converter 19 is changed until the logic of the voltage comparator 2 is inverted, and the output from the D/A converter 2 at the time when the logic of the voltage comparator 2 is inverted is stored in the memory 16 in step S19.

Next, the process returns to step S16, and the output from the driver is set to the “L” level. Steps S17 and S18 are performed on the output from the driver at the “L” level, and the output from the D/A converter 2 at the time when the logic of the voltage comparator 2 is inverted is stored in the memory 16 in step S19.

In step S20, a difference between the voltage values of the measured driver at the “H” level and “L” level (i.e., the amplitude of the voltage output from the driver) is calculated by the controller 15, and in step S21, the amplitude of the output from the driver is recorded in the memory 16. It is to be understood that the set value of the driver amplitude set in step S16 is actually output as a value recorded here.

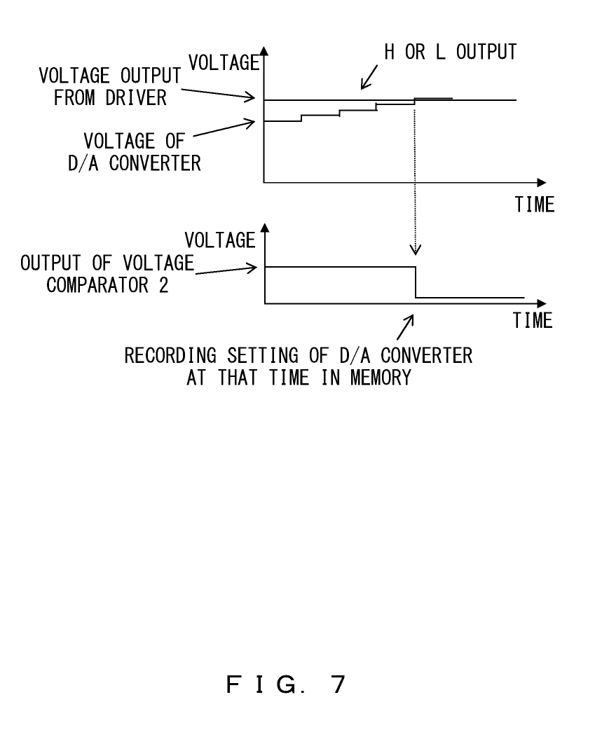

FIG. 7 illustrates how the set value of the voltage at the D/A converter 19 is set.

FIG. 7 illustrates the case in which the voltage output from the driver is greater than the voltage at the D/A converter 19. The voltage output from the driver is at one of the “H” level and “L” level, and the voltage at both the “H” level and “L” level is compared with the voltage at the D/A converter 19. In the case of FIG. 7, the level of the voltage at the D/A converter 19 is increased by one step at a time, and a voltage value of the D/A converter 19 at the time when the logic output from the voltage comparator 2 is inverted is stored in the memory 16. When the voltage output from the driver is smaller than the voltage at the D/A converter 19, the level of the voltage at the D/A converter 19 is decreased by one step at a time, and a voltage value of the D/A converter 19 at the time when the logic of the voltage comparator 2 is inverted is stored in the memory 16. The inversion of the logic of the voltage comparator 2 indicates that the point at which the voltage output from the driver is equal to the voltage at the D/A converter 19 is crossed, and thus it can be said that the voltage at the D/A converter 19 at this point indicates the voltage output from the driver.

For example, the output amplitude of a driver is set to 400 mV (value of H−L), and the “H” level is output. The setting of the voltage at the D/A converter 19 is set to 700 mV (n.b., the set value and voltage value obtained in the calibration of the D/A converter 19 are used for the value at this time), and the voltage is output to the voltage comparator 2. The output from the voltage comparator 2 is discerned by the controller 15. When “1” is obtained as a result of the discernment process, the level of the setting is increased by one step so as to increase the voltage at the D/A converter 19, and the output from the voltage comparator 2 is discerned again. This is repeated until the output from the voltage comparator 2 changes to “0”. When the setting of the D/A converter 19 is 790 mV and the output from the voltage comparator 2 is changed to “0”, the voltage value of the driver at the “H” level becomes 790 mV and this value is recorded in the memory 16.

Next, the output from the driver is inverted to the “L” level. Then, the D/A converter 19 is set to 500 mV, and the voltage is output to the voltage comparator 2. When “0” is obtained by using the controller as a result of the discernment process of the output from the voltage comparator 2, the level of the setting is reduced by one step so as to reduce the voltage at the D/A converter 19, and the output from the voltage comparator 2 is discerned again. This is repeated until the output from the voltage comparator 2 changes to “1”. When the setting of the D/A converter 19 is 410 mV and the output from the voltage comparator 2 is changed to “1”, the voltage value of the driver at the “L” level becomes 410 mV and this value is stored in the memory 16.

Next, the controller 15 subtracts the voltage value at the “L” level from the previously stored voltage value at the “H” level, and the amplitude value of 380 mV is obtained.

This indicates that when the amplitude of the driver is set to 400 mV, the voltage whose amplitude is 380 mV is actually being output. When 400 mV is set as above, the information indicating the voltage of 380 mV is stored in the memory 16.

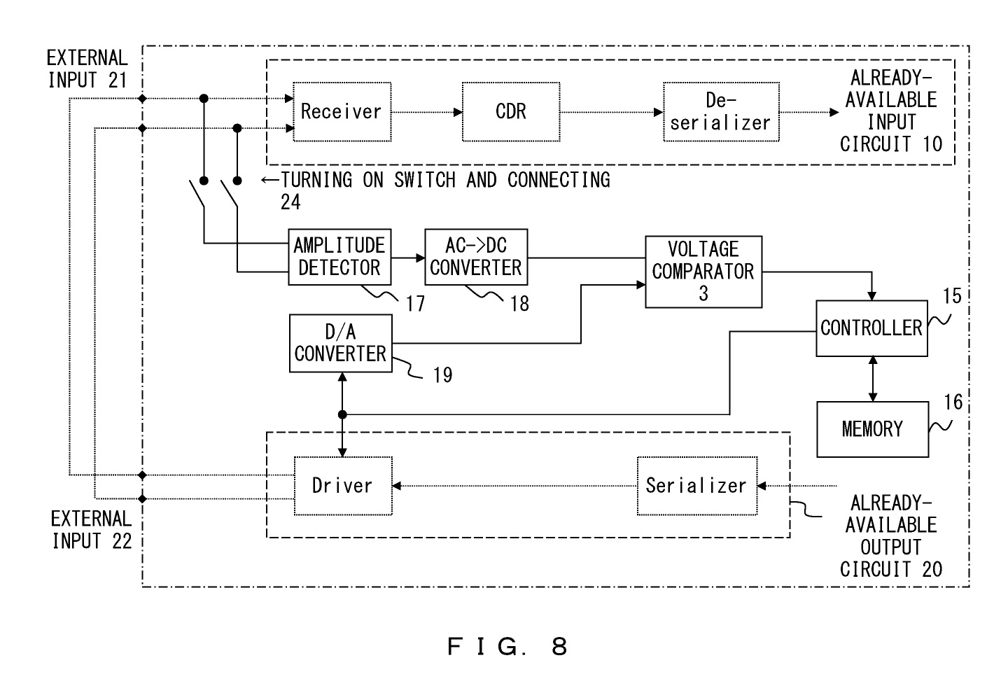

FIGS. 8 to 10 illustrate how an input amplitude detector is calibrated.

Here, an input amplitude detector is calibrated. This calibration is performed so as to eliminate a difference in the voltage value detected in each semiconductor device, caused due to variations in the manufacturing or the like.

FIG. 8 focuses on a circuit used for calibrating an input amplitude detector. The calibration of an input amplitude detector is performed by inputting to the external input 21 the external output 22 of the driver of the already-available output circuit 20 whose output amplitude is calibrated at an earlier stage.

The amplitude of the driver is set (i.e., a value obtained as a result of the calibration of the output amplitude is used), and 01 alternating data of a few GHz (AC voltage) is output. Its signal is detected by the amplitude detector 17, and the AC-to-DC converter 18 converts the signal to a DC level (raising it to a DC level by applying a bias voltage thereto) and inputs the converted signal to the voltage detector 3. Next, a transient voltage is set to the D/A converter 19, and this transient voltage is input to the voltage comparator 3. Here, the transient voltage is set by using a value obtained in the calibration of the D/A converter 19. Then, the logic output from the voltage comparator 3 is discerned by the controller 15. When the output from the voltage comparator 3 is 01 alternating data at this time, the flow of voltage detection is performed.

When the output from the voltage comparator 3 is not 01 alternating data, the logic at that time is checked and the setting of the voltage at the D/A converter 19 is changed such that 01 alternating data will be output. In other words, the voltage at the D/A converter 19 is set so as to be smaller than the “H” level of the output voltage from the AC-to-DC converter 18 and greater than the “L” level of the output voltage from the AC-to-DC converter 18.

In the flow of voltage detection, a voltage value on the “H” level side is firstly detected. The level of the setting is increased by one step so as to increase the voltage output from the D/A converter 19, and the output from the voltage comparator 3 is checked (cases will be described in which “1” is obtained when the voltage at the D/A converter 19 is smaller than the output voltage from the AC-to-DC converter 18 and “0” is obtained when the voltage at the D/A converter 19 is greater than the output voltage from the AC-to-DC converter 18). The resetting process of the voltage at the D/A converter 19 is repeated until the output from the voltage comparator 3 continuously indicates data of “0” for more than 3 bits (i.e., more than 3 clock signal cycles (specified number of cycles)). The set value (voltage value) of the D/A converter 19 at the time when the output from the voltage comparator 3 has continuously output “0” for more than 3 bits (i.e., more than 3 clock signal cycles (specified number of cycles)) is recorded in the memory 16.

Next, a voltage value on the “L” level side is detected. The setting of the D/A converter 19 is changed to the originally set value. Next, the level of the setting is reduced by one step so as to decrease the voltage output from the D/A converter 19, and the output from the voltage comparator 3 is checked. The resetting process of the voltage at the D/A converter 19 is repeated until the output from the voltage comparator 3 continuously indicates data of “1” for more than 3 bits (i.e., more than 3 clock signal cycles (specified number of cycles)). The set value (voltage value) of the D/A converter 19 at the time when the output from the voltage comparator 3 has continuously output “1” for more than 3 bits (i.e., more than 3 clock signal cycles (specified number of cycles)) is recorded in the memory 16.

Accordingly, voltages at the “H” level and “L” level maybe detected, and the amplitude value maybe calculated. An amplitude value obtained as a result of the calibration of the output amplitude is compared with an amplitude value obtained as a result of the calibration of the input amplitude detector so as to calculate a difference. Then, the result (voltage value corresponding to the difference) is stored in the memory 16.

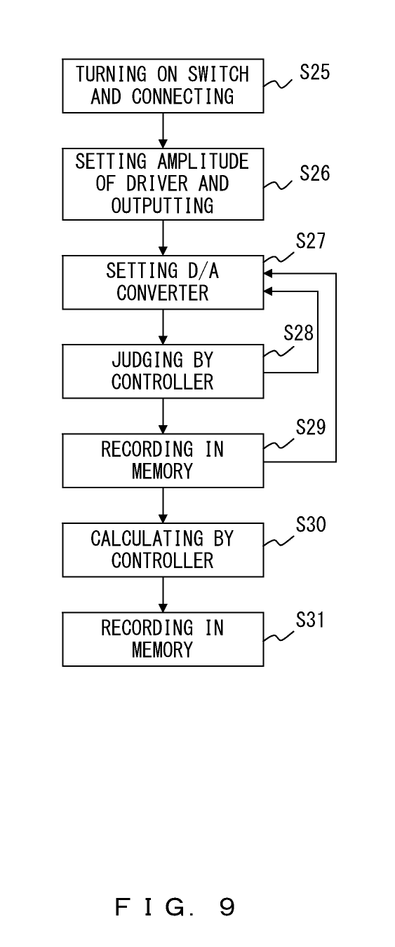

FIG. 9 is a flowchart illustrating the calibration performed by the input amplitude detector. Firstly, in step S25, the controller 15 turns on the switch 24 according to the mode setting. In step S26, the amplitude value of the driver is set (a value obtained as a result of the calibration of the output amplitude is used), and a 01 alternating data signal of a few GHz is output. Its signal is detected by the amplitude detector 17, and the AC-to-DC converter 18 converts the signal to a DC level (raising to a DC level by applying a bias voltage thereto) and inputs the converted signal to the voltage comparator 3. In step S27, a transient voltage of the voltage output from the D/A converter 19 is set, and a transient voltage is output. Here, the transient voltage is set by using a value obtained in the calibration of the D/A converter 19. In step S28, the voltage comparator 3 compares the voltage at the AC-to-DC converter 18 with the voltage at the D/A converter 19. The voltage at the D/A converter 19 is set so as to be smaller than the “H” level of the output voltage from the AC-to-DC converter 18 and greater than the “L” level of the output voltage from the AC-to-DC converter 18. As a result, the output from the voltage comparator 3 becomes a 01 alternating signal. It is assumed that “1” is output when the voltage at the AC-to-DC converter 18 is greater than the voltage at the D/A converter 19 and “0” is output when the voltage at the AC-to-DC converter 18 is smaller than the voltage at the D/A converter 19. The voltage at the D/A converter 19 is gradually increased, and the voltage at the D/A converter 19 at the time when “0” is continuously output a specified number of times (three times) is stored in the memory 16 as a voltage at the “H” level of the AC-to-DC converter 18 (step S29). Next, the voltage at the D/A converter 19 is reset to a voltage value obtained when the output voltage from the AC-to-DC converter 18 is set to be smaller than the “H” level and greater than the L” level. The voltage at the D/A converter 19 is gradually decreased, and the voltage at the D/A converter 19 at the time when “1” is output a specified number of times (for example, three times) is stored in the memory 16 as a voltage at the “L” level of the AC-to-DC converter (step S29). In step S30, the controller 16 calculates a difference between a voltage at the “H” level and a voltage at the “L” level of the AC-to-DC converter 18, all of which are stored in the memory 16 (step S30). Then, the calculation result is determined to be an amplitude detection value of the input amplitude detector. Then, a difference between the above amplitude detection value and an amplitude detection value obtained as a result of the calibration of the output amplitude is recorded in the memory 31.

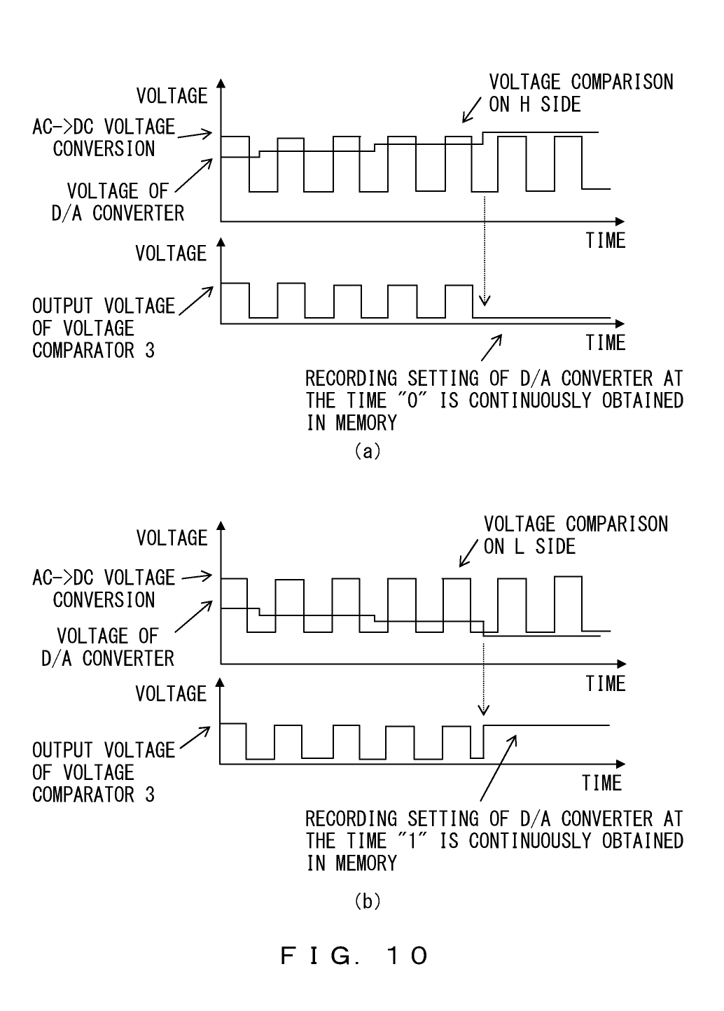

FIG. 10 illustrates how the set value of the voltage at the D/A converter 19 is set.

Firstly, the voltage at the D/A converter 19 is set to be smaller than the “H” level of the output voltage from the AC-to-DC converter 18 and greater than the “L” level of the output voltage from the AC-to-DC converter 18. When the “H” level of the output voltage from the AC-to-DC converter 18 is detected, the level of the voltage at the D/A converter 19 is increased by one step at a time, and a voltage value of the D/A converter 19 at the time when the logic output from the voltage comparator 3 has continuously indicated that the voltage at the D/A converter 19 becomes larger a specified number of times is stored in the memory 16. When the “L” level of the output voltage from the AC-to-DC converter 18 is detected, the level of the voltage at the D/A converter 19 is decreased by one step at a time, and a voltage value of the D/A converter 19 at the time when the logic output from the voltage comparator 3 has continuously indicated that the voltage at the D/A converter 19 becomes smaller a specified number of times is stored in the memory 16.

For example, the amplitude of the driver is set to 400 mV. Then, 01 alternating data is output. Next, the setting of the voltage of the D/A converter 19 is set to 600 mV. Then, the output from the voltage comparator 3 is discerned by the controller 15, and when the output logic is determined to be 01 alternating data, the level of the output from the voltage comparator 3 is increased by one step so as to increase the voltage of the D/A converter. The output from the voltage comparator 3 is discerned again, and the discernment process is repeated until data of “0” is continuously obtained for more than 3 bits (i.e., more than 3 clock signal cycles (specified number of cycles)). The set value (voltage value) of the D/A converter 19 at the time when data of “0” is continuously obtained for more than 3 bits (i.e., more than 3 clock signal cycles (specified number of cycles)) is recorded in the memory 16 (for example, data of 780 mV is recorded).

Next, the setting of the voltage of the D/A converter 19 is returned to 600 mV. Then, the level of the output from the voltage comparator 3 is decreased by one step so as to decrease the voltage at the D/A converter 19, and the output from the voltage comparator 3 is discerned. Then, the discernment process is repeated until data of “1” is continuously output for more than 3 bits (i.e., more than 3 clock signal cycles (specified number of cycles)). The set value (voltage value) of the D/A converter 19 at the time when data of “1” is continuously obtained for more than 3 bits (i.e., more than 3 clock signal cycles (specified number of cycles)) is recorded in the memory 16 (for example, data of 420 mV is recorded).

Accordingly, the amplitude detection value obtained from the input amplitude detector becomes 360 mV. As described above with reference to FIG. 7, the value of the output amplitude of a driver is 380 mV (the setting is 400 mV), and thus it is revealed that a difference of 20 mV is caused due to variations in the manufacturing or the like of the input amplitude detector. The value of the difference is recorded in the memory 16, and an amplitude correction of 20 mv is performed for the amplitude value detected by the input amplitude detector.

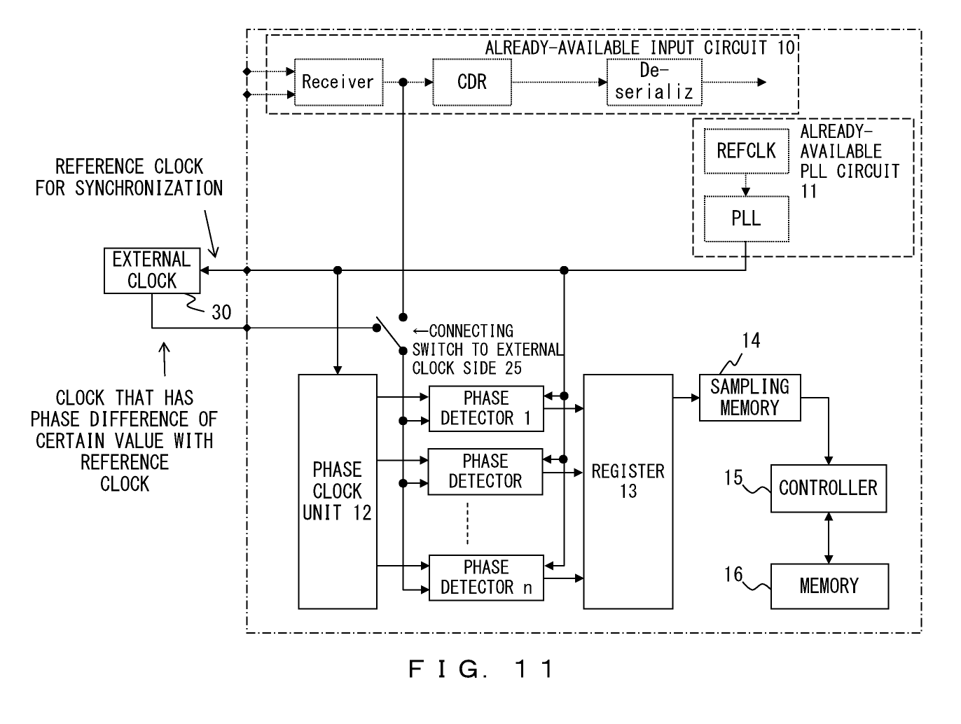

FIGS. 11 to 13 illustrate how a phase detection circuit is calibrated.

Next, a phase detection circuit is calibrated. This calibration is performed so as to eliminate a difference in the phase detection circuits of each semiconductor device, which is caused due to variations in the manufacturing or the like.

FIG. 11 focuses on a circuit used for calibrating a phase detection circuit.

Firstly, a reference clock output from the already-available PLL circuit 11 is output to an external clock 30 in order to perform synchronization. Secondly, the external clock 30 inputs to each of the phase detectors 1 to n (comparators) a clock that has a phase difference of a certain value with a reference clock and has jitter within 0.01 UI (Unit Intervals; the value of UI is to be set as necessary by a person skilled in the art). This clock is compared with phase clock signals that have phase differences of 1 to n from 0.01 UI to 0.0n UI from a reference clock at 0.01 UI intervals, which are generated by the phase clock unit 12, and then phase detection is performed. Moreover, reference clocks from the already-available PLL circuit 11 are input to the phase detectors 1 to n. The phase detectors 1 to n compare an external clock with a phase clock signal from the phase clock unit 12 with the timing at which a reference clock rises, and output the resultant logic. Then, the logic of the comparison result is written into the register 13 with the next timing at which a reference clock rises. The data written in the register 13 by the phase detectors 1 to n is written into the sampling memory 14 with the next timing at which a reference clock falls, and then phase detection is performed again. When both the external clock and the phase clock signal are “1”, the output of the phase detector becomes “1”. On the other hand, when one of the external clock and the phase clock signal is “1” and the other is “0”, the output of the phase detector becomes “0”. As phase clock signals with different phase differences are input to the phase detectors 1 to n, for example, the output of phase detectors 1 to k becomes “1”, and the output of phase detectors k+1 to n becomes “0”. In this case, the output of the phase detector k+1 is performed with the timing at which the logic is inverted, and thus it is judged that the phase difference of the phase clock signal input to the phase detector k+1 is the phase difference that the external clock has.

The process is repeated a specified number of times, and the controller 15 calculates an average value of the phase difference and the amount of jitter (minimum phase value−maximum phase value) by using the detected data. According to the result, the controller 15 checks a phase clock signal that has a certain phase value to determine whether the resultant average value is within ±0.1 UI. When there is no problem, the amount of jitter obtained by subtracting 0.01 UI from the measured amount of jitter is recorded in the memory 16. If the resultant average value is equal to or greater than ±0.1 UI, there is a possibility that the detector is under abnormal conditions. In that case, the controller 15 sends an error notification to test control computer through the external communication port.

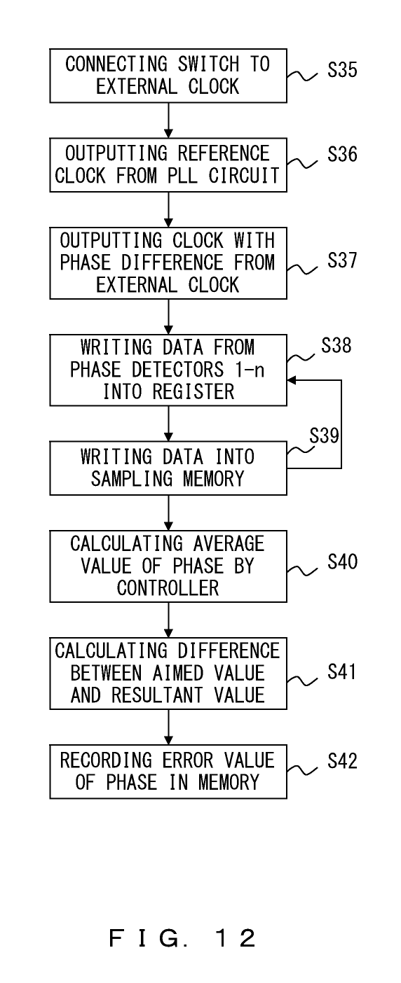

FIG. 12 is a flowchart illustrating the calibration performed by the phase detection circuit.

In step S35, the controller 15 connects the switch 25 to the external clock 30 according to the designated mode. In step S36, the already-available PLL circuit 11 outputs a reference clock. In step S37, the external clock 30 outputs a clock with a phase difference value that is preliminarily set to the reference clock. In step S38, each of the phase detectors 1 to n compares clock signals output from the external clock 30 with the phase clock signals having phase difference values generated by the phase clock unit 12, and writes the resultant data into the register 13. In regard to the comparison result of the phase detectors 1 to n, when both the phase clock signal and the external clock have “1”, for example, “1” is output, and when one of the phase clock signal and the external clock has “0”, for example, “0” is output. This is referred to as the logic of the comparison result. As the register 13 stores only the result of one-time phase detection, the register 13 writes the data into the sampling memory 14 in step S39 after the process of one-time phase detection is completed. Such processes of phase detection are repeated for the previously determined number of times. In step S40, the controller 15 calculates an average value of the detected phase and the amount of jitter. In step S41, the controller 15 calculates a difference between the phase value and the amount of jitter of an external clock and the phase value and the amount of jitter obtained in step S40. When no problem is found in a difference between an average value of the measured phase value and a previously determined phase value (i.e., a difference of the phase value is within a specified range), the controller 15 records a difference between the measured amount of jitter and the previously determined amount of jitter in the memory 16 (step S42).

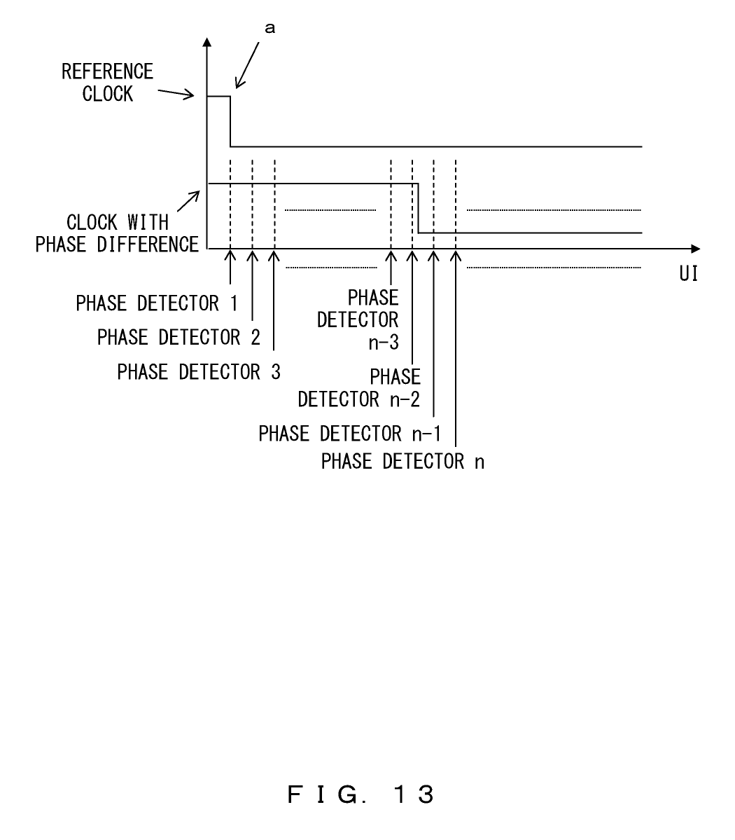

FIG. 13 illustrates how phase detection is performed.

The external clock 30 generates a clock with a certain phase difference with reference to a reference clock. Each of the phase detectors 1 to n receives from the phase clock unit 12 phase clock signals that have phase differences of 1 to n at 0.01 UI intervals, and compares the received phase clock signals with clock signals from the external clock. For example, in the example case of FIG. 13, a phase difference of a phase clock signal detected by a phase detector k with reference to a reference clock is “(0.01×(k−1)) UI”. The timing at which a phase clock signal is compared with a clock signal with a phase difference output from the external clock is equivalent to, for example, timing “a” at which a reference clock falls. Among neighboring phase detectors with phase differences, the phase of the phase detector where the logic of the comparison result is inverted becomes the detected phase. In other words, when the logic of the comparison result among the phase detectors 1 to k is “1” and the logic of the comparison result among the phase detectors k+1 to n is “0”, the phase of the phase clock signal input to the phase detector k+1 becomes the phase of the external clock. In FIG. 13, the logic of the phase detectors 1 to n-2 is “1”, and the logic of the phase detectors n-1 to n is “0”. Accordingly, the detected phase becomes the phase of the phase clock signal that is input to the phase detector n-1.

For example, the clock having a phase difference of 0.30 UI and an amount of jitter of 0.01 UI is output from the external clock 30 to a reference clock. The logic of each phase is detected by performing phase detection for the clock with phase differences at 0.01 UI intervals. Assume that the process is repeated ten times, and results of 0.31 UI, 0.32 UI, 0.33 UI, 0.34 UI, and 0.35 UI are obtained once, twice, six times, twice, and once, respectively. As a result, the average value of the phase difference becomes 0.33 UI, and the amount of jitter becomes 0.04 UI.

In this case, the phase difference of 0.33 UI with reference to 0.30 UI is within the error of ±0.1 UI, and thus it is determined that no problem is present in the measurement. In regard to the amount of jitter, 0.03 UI obtained by subtracting the original amount of jitter 0.01 UI from the result of 0.04 UI becomes a difference in the detection of the amount of jitter, and the resultant data is recorded in the memory 16.

In the test by the semiconductor device, the resultant value obtained by correcting the measured amount of jitter by the difference of 0.03 UI becomes the normal amount of jitter.

Next, the semiconductor device performs a test to determine whether the standards are met.

An instruction to shift to the test mode is transmitted to the controller 15 via the external communication port. Once an instruction to shift to the test mode is received, the controller 15 sets up a register for the device test mode, and performs a test for the input amplitude and input jitter, or the like.

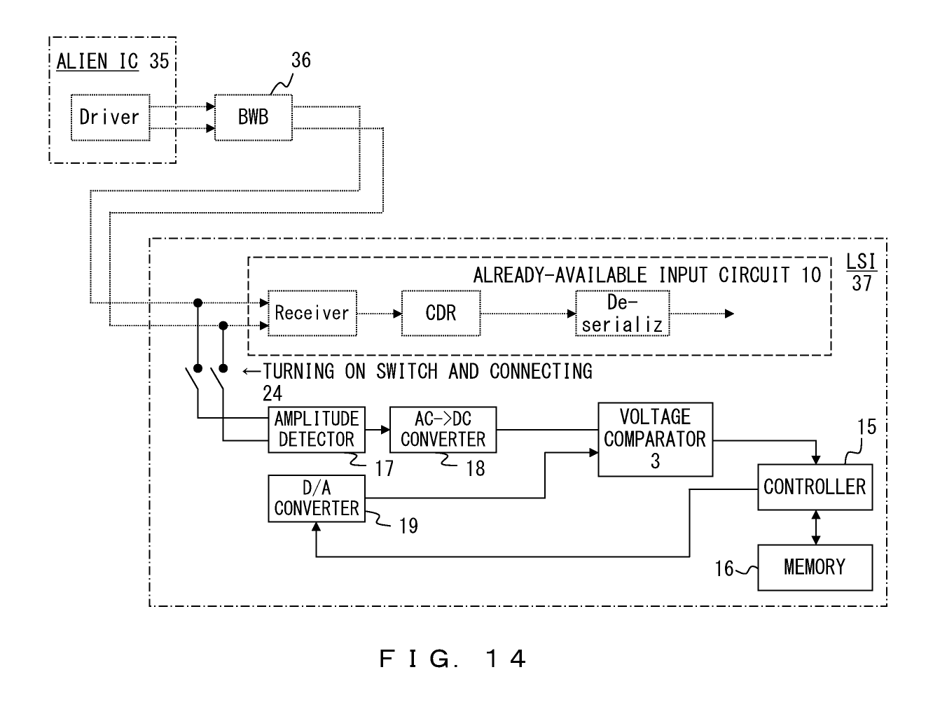

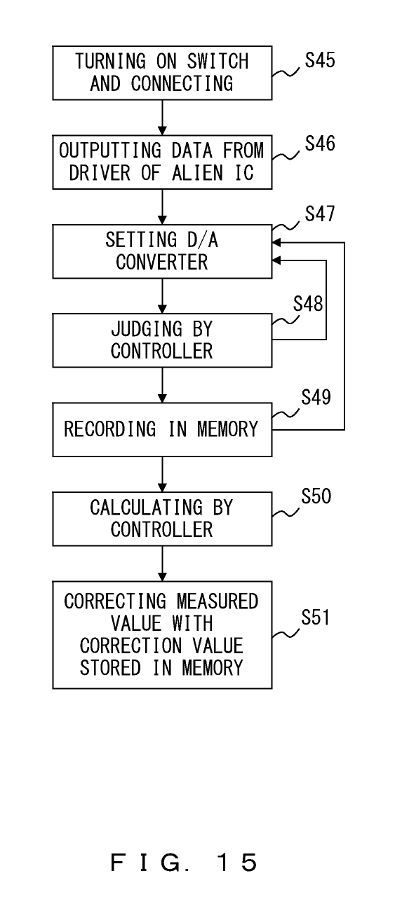

FIGS. 14 and 15 illustrate the processes of detecting the amplitude values of the signals input from other drivers, and the processes of performing a test for standard values or the like.

FIG. 14 focuses on the configuration for performing detection and testing of the amplitude values of the signals input from other drivers.

The output signal from the driver of an alien IC 35 provided for the device is connected to the receiver of the already-available input circuit 10 of a main LSI circuit 37, and 01 alternating data is output from the driver of the alien IC 35. The signals output from the driver of the alien IC 35 are input to the main LSI circuit 37 through a wiring board (BWB) 36. Those signals are detected by the amplitude detector 17 and are converted by the AC-to-DC converter 18 to a DC level (a level at which the minimum level of a signal is equal to or greater than 0V), and are input to the voltage detector 3. Next, a transient voltage is set to the D/A converter 19, and this transient voltage is input to the voltage comparator 3. The transient voltage is set such that a “01” alternating voltage will be output from the voltage detector 3. Here, the transient voltage is set by using a value obtained in the calibration of the D/A converter 19. Then, the logic output from the voltage comparator 3 is discerned by the controller 15, and the D/A converter 19 is controlled.

Firstly, a voltage value on the “H” level side of the signal output from the AC-to-DC converter 18 is detected. The level of the setting is increased by one step so as to increase the voltage output from the D/A converter 19, and the output from the voltage comparator 3 is checked. This process is repeated until the output from the voltage comparator 3 continuously indicates data of “0” for more than 3 bits (i.e., more than 3 clock signal cycles (specified number of cycles)) (it is assumed that the voltage comparator 3 outputs “0” when the voltage at the D/A converter 19 is greater than the voltage value of the signal output from the AC-to-DC converter 18). The set value (voltage value) of the D/A converter 19 at the time when the output from the voltage comparator 3 has continuously output “0” for more than 3 bits (i.e., more than 3 clock signal cycles (specified number of cycles)) is recorded in the memory 16.

Secondly, a voltage value on the “L” level side of the signal output from the AC-to-DC converter 18 is detected. The setting of the D/A converter 19 is changed to the originally set value. Then, the level of the setting is reduced by one step so as to decrease the voltage output from the D/A converter 19, and the output from the voltage comparator 3 is checked. This process is repeated until the output from the voltage comparator 3 continuously indicates data of “1” for more than 3 bits (i.e., more than 3 clock signal cycles (specified number of cycles)). The set value (voltage value) of the D/A converter 19 at the time when the output from the voltage comparator 3 has continuously output “1” for more than 3 bits (i.e., more than 3 clock signal cycles (specified number of cycles)) is recorded in the memory 16. The amplitude of the voltage output from the AC-to-DC converter 18 is calculated by using the resultant data, and the calculated amplitude is corrected by the controller 15 using a correction value obtained in the calibration of the input amplitude detector. The correction value may be a positive or negative value, and thus the measured value may be corrected by adding the correction value to the measured voltage that is stored in the memory 16. It is determined whether the correction value meets the standards, and the resultant data is sent through an external output port. A test control computer is connected to the external output port, and the above determination result is displayed on a screen as a determination result of the test.

FIG. 15 is a flowchart of the processes of performing detection and testing of the amplitude values of the signals input from other drivers. In step S45, the controller 15 turns on the switch 24 according to the mode setting. In step S46, a 01 alternating data signal is output from the driver of the alien IC 35. In step S47, the voltage output from the D/A converter 19 is set as a transient voltage between the “H” level and “L” level of the signals output from the driver of the alien IC 35. Here, the transient voltage is set by using a value obtained in the calibration of the D/A converter 19. In step S48, an output voltage from the voltage comparator 3 is discerned (step S48). Firstly, the setting is changed so as to increase the level of the voltage at the D/A converter 19 by one step, and the output voltage is discerned by the voltage comparator 3. Then, the periodicity at which the voltage at the D/A converter 19 becomes greater than the signal output from the AC-to-DC converter 18 is measured. When the measured value reaches a specified value (for example, 3), a voltage value of the D/A converter 19 at that time is stored in the memory 16 as a voltage from the AC-to-DC converter 18 at the “H” level (step S49). Next, the voltage at the D/A converter 19 is restored and the setting is changed so as to decrease the level of the voltage at the D/A converter 19 by one step, and the output voltage is discerned by the voltage comparator 3. Then, the periodicity at which the voltage at the D/A converter 19 becomes smaller than the signal output from the AC-to-DC converter 18 is measured. When the measured value reaches a specified value (for example, 3), a voltage value of the D/A converter 19 at that time is stored in the memory 16 as a voltage from the AC-to-DC converter 18 at the “L” level (step S49). In step S50, an amplitude value is calculated by subtracting the measured voltage at the “L” level from the measured “H” level. In step S51, correction is performed by adding a correction value stored in the memory 16 for the input amplitude value of the input amplitude detector obtained in the calibration to the amplitude value obtained as a result of the subtraction. The corrected amplitude value is used to determine whether or not the standard value is met.

For example, when a standard value for amplitude is a voltage greater than 200 mV but the detected voltage amplitude is 400 mV, the voltage amplitude is corrected to 420 mV by a correction value (in the case of 20 mV). As the standards are met by exceeding 200 mV, notification that there is no problem is sent to a test control computer via the external communication port 26. When the detected voltage is 160 mV, the standards of 200 mV are not met because the voltage corrected by a correction value (20 mV) is still 180 mV. Thus, notification that a problem is present is sent to the test control computer via the external communication port 26.

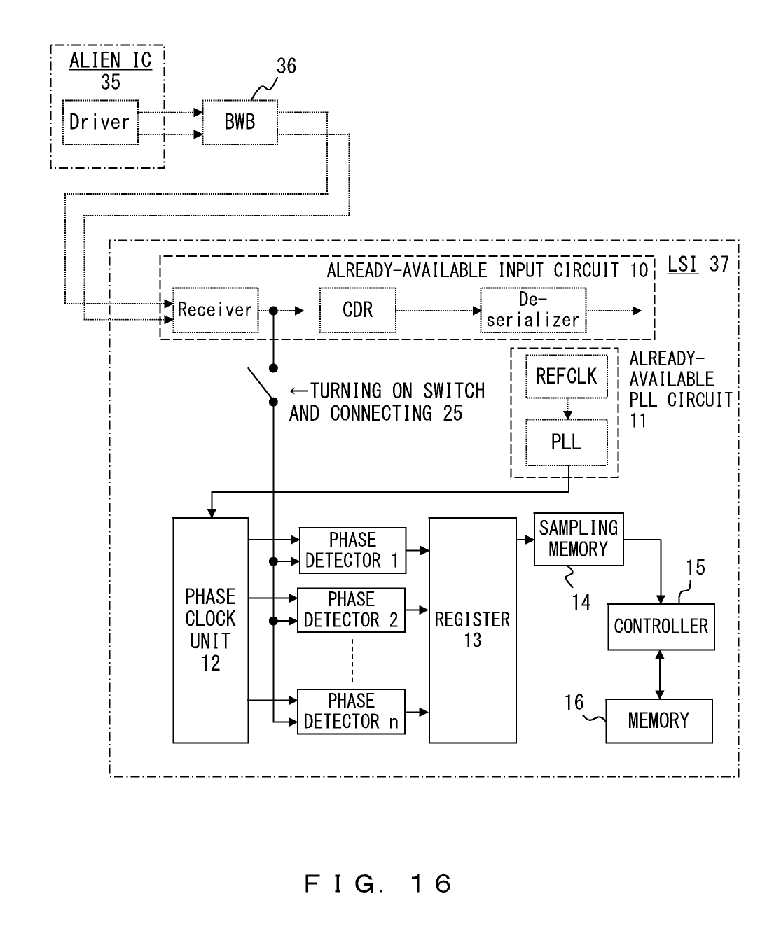

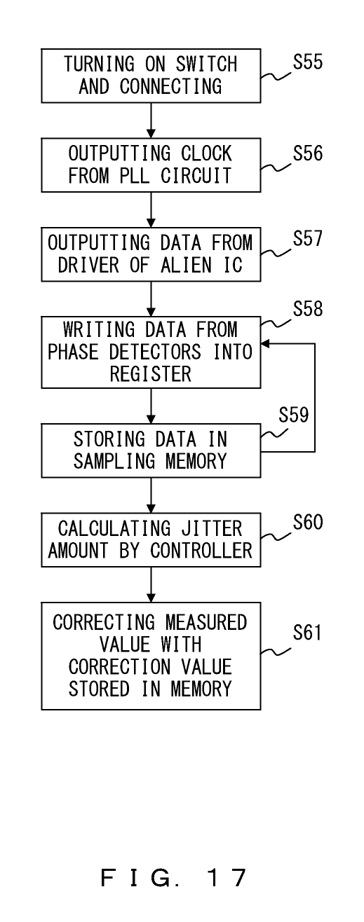

FIG. 16 and FIG. 17 illustrate the processes of detecting the amount of jitter of the signals input from other drivers and performing a test for standard values or the like.

FIG. 16 focuses on the illustration of the configuration used for the processes of measuring the input jitter and discerning the measured input jitter according to the standard value or the like.

The output signal from the driver of an alien IC 35 provided for the device is connected to the receiver of the already-available input circuit 10 of the main LSI circuit 37, and a 01 alternating data signal is output from the driver of the alien IC 35. The signal output from the driver is input to the receiver, and is output from the receiver to the CDR and the phase detectors 1 to n. The phase detectors 1 to n are provided with n comparators, and phase clock signals that have phase differences at 0.01 UI intervals are output from the phase clock unit 12 to the phase detectors 1 to n, respectively. The phase detectors 1 to n detect phases of 01 data signals at 0.01 UI intervals, and write the detected phases into the register 13 and store the written data in the sampling memory 14. The above process is repeated a specified number of times (for example, hundreds of times), and the controller 15 calculates the amount of jitter according to the information stored in the sampling memory 14. Once the amount of jitter is calculated, the amount of jitter is corrected by using a correction value stored in the memory 16 to see whether the corrected amount of jitter meets a standard value or the like. When the logic of the comparison result is “1” up to the phase detectors 1 to k and the logic of the comparison result is “0” at the phase detectors k+1 to n, the phase of the phase clock signal input to the phase detector k+1 becomes the phase of the signal from the receiver.

In the description above, the output from the receiver of the input circuit 10 is input to the phase detection circuits 1 to n to detect phases. This indicates that the receiver includes a terminating resistor therein, and a signal is sampled at a rear stage of the terminating resistor. If the signal does not go through the terminating resistor, it becomes impossible to accurately detect a phase as the signal reflects and the waveform becomes distorted. For this reason, a signal is sampled at a rear stage of the receiver in the phase detection.

FIG. 17 is a flowchart of the processes of detecting and testing the jitter value of the signals input from other drivers.

In step S55, the controller 15 connects the switch 25 toward the direction of the receiver according to the mode setting. In step S56, a clock is output from the already-available PLL circuit 11. In step S57, the driver of the alien IC 35 outputs a 01 alternating data signal. This data signal is input to the phase detectors 1 to n. Moreover, phase clock signals generated from the clock by the phase clock unit 12 with varying phase differences by a specified value are input to the phase detectors 1 to n. The phase detectors 1 to n compare the input phase clock signals with the data signal, and write the resultant data into the register 13 (step S58). The data written in the register 13 is input to the sampling memory 14 and is stored therein (step S59). The above phase detection is performed a specified number of times. The controller 15 calculates the amount of jitter of the above data signal according to the phase detection result stored in the sampling memory 14 (step S60). The calculated amount of jitter is corrected by using a correction value (step S61) that is stored in the memory 16 and is obtained in the calibration of the phase detection circuit, and it is determined whether or not the corrected amount of jitter meets a standard value or the like. As the correction value is a positive or negative value, the amount of jitter may be corrected by adding a correction value to the measured amount of jitter.

If the standard value for the amount of jitter is, for example, 0.60 UI, and when the detected amount of jitter is 0.50 UI and the corrected amount is 0.47 UI (in the case of a correction value being 0.03 UI), the standard value is satisfied and thus notification that there is no problem is sent to the test control computer. When the detected value is 0.65 UI and the corrected value is 0.62 UI (in the case of a correction value being −0.03 UI), the standard value is not satisfied and thus notification that a problem is present is sent to the test control computer.

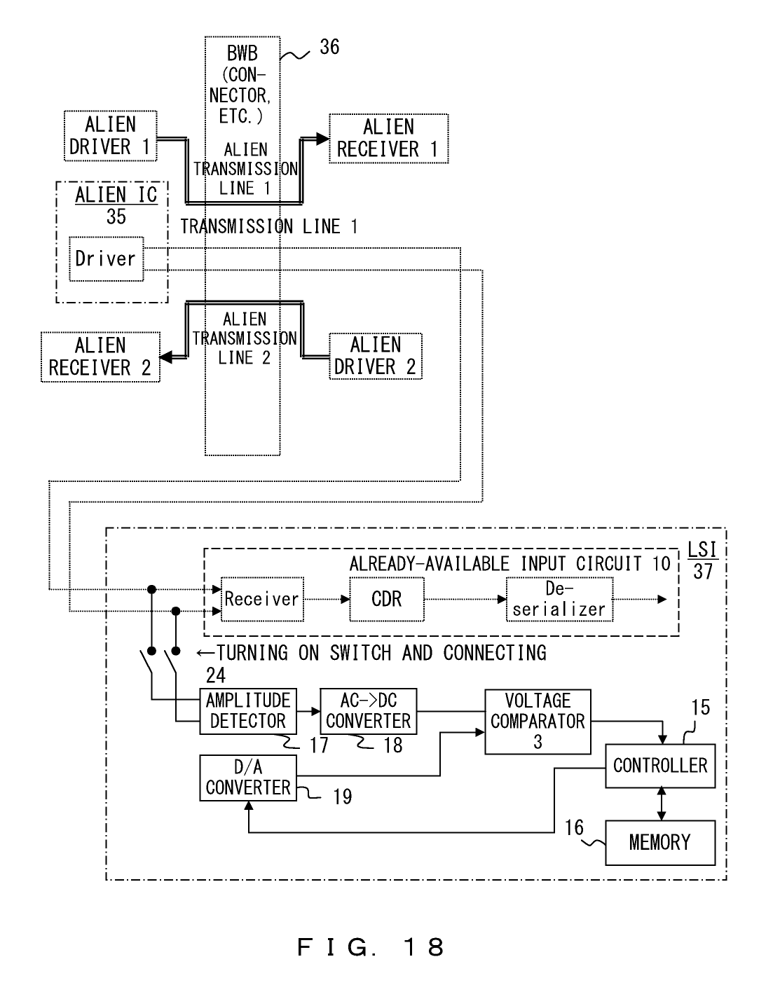

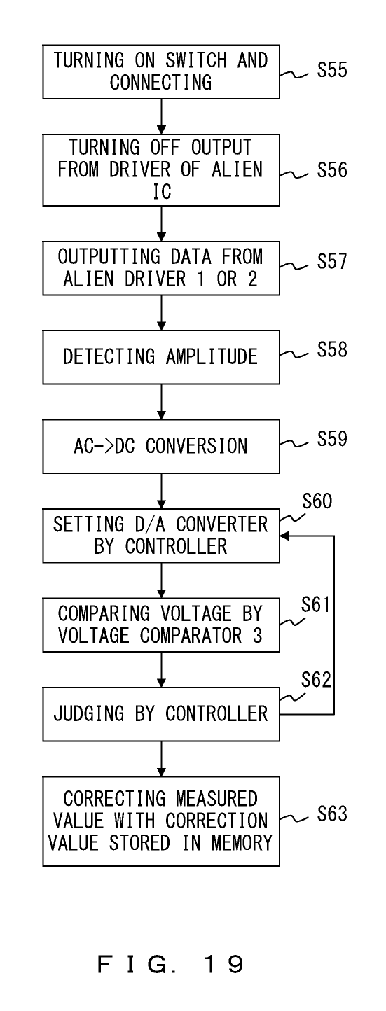

FIG. 18 and FIG. 19 illustrate the application of the present embodiment where the amount of crosstalk from an alien transmission line or several alien transmission lines is detected and judged according to an aimed value or the like.

FIG. 18 focuses on the illustration of the configuration used for detecting crosstalk and judging the detected crosstalk according to an aimed value or the like.

A transmission line 1 that connects the driver of the alien IC 35 with the receiver of the already-available input circuit 10 of the main LSI circuit 37 is equipped on a wiring board 36 together with an alien transmission line 1 that connects an alien driver 1 with an alien receiver 1 and an alien transmission line 2 that connects an alien driver 2 with an alien receiver 2. In such cases, signals from the alien drivers 1 and 2 may interfere with the transmission line 1 as crosstalk. The detection of such crosstalk will be described.

Firstly, the output from the driver of the alien IC 35 is terminated, and 01 alternating data is output from the alien driver 1. Then, a crosstalk signal input to the receiver of the main LSI circuit 37 is detected by the amplitude detector 17, and the detected crosstalk signal is converted to a DC level by the AC-to-DC converter 18 and is input to the voltage detector 3. Next, a transient voltage is set to the D/A converter 19, and this transient voltage is input to the voltage comparator 3. Here, the transient voltage is set by using a value obtained in the calibration of the D/A converter 19. Then, the logic output from the voltage comparator 3 is discerned by the controller 15, and the D/A converter 19 is controlled.

Firstly, a voltage value on the “H” level side is detected from the crosstalk of the 01 alternating data signal output from the alien driver 1. A transient voltage value at the D/A converter 19 is configured so as to be between a voltage value at the “H” level and “L” level of the 01 alternating data signal output from the alien driver 1. This is achieved by configuring the output from the voltage detector 3 to be equivalent to the 01 alternating signal. Secondly, the level of the setting is increased by one step so as to increase the voltage output from the D/A converter 19, and the output from the voltage comparator 3 is checked. This process is repeated until the output from the voltage comparator 3 continuously indicates data of “0” for more than 3 bits (i.e., more than 3 clock signal cycles (specified number of cycles)) (it is assumed that “0” is output when the voltage at the D/A converter 19 is greater than the voltage output from the AC-to-DC converter 18 and “1” is output when the voltage at the D/A converter 19 is smaller than the voltage output from the AC-to-DC converter 18). The set value (voltage value) of the D/A converter at the time when the output from the voltage comparator 3 has continuously output “0” for more than 3 bits (i.e., more than 3 clock signal cycles (specified number of cycles)) is recorded in the memory 16.

Next, a voltage value on the “L” level side is detected from the crosstalk of the 01 alternating data signal output from the alien driver 1. The setting of the voltage at the D/A converter 19 is changed to the originally set value. Then, the level of the setting is reduced by one step so as to decrease the voltage output from the D/A converter 19, and the output from the voltage comparator 3 is checked. This process is repeated until the output from the voltage comparator 3 continuously indicates data of “1” for more than 3 bits (i.e., more than 3 clock signal cycles (specified number of cycles)). The set value (voltage value) of the D/A converter 19 at the time when the output from the voltage comparator 3 has continuously output “1” for more than 3 bits (i.e., more than 3 clock signal cycles (specified number of cycles)) is recorded in the memory 16.

Alternatively, a device may include two or more alien drivers, alien receivers, and alien transmission lines, and 01 alternating data is output from several alien drivers. The output from the driver of the alien IC 35 is terminated, and the crosstalk input to the receiver of the main LSI circuit 37 is detected by the amplitude detector 17. Then, the detected amplitude is converted to a DC level by the AC-to-DC converter 18 and is input to the voltage comparator 3. Next, a transient voltage is set to the D/A converter 19, and this transient voltage is input to the voltage comparator 3. Here, the transient voltage is set by using a value obtained in the calibration of the D/A converter 19. Then, the logic output from the voltage comparator 3 is discerned by the controller 15, and the D/A converter 19 is controlled. A transient voltage value at the D/A converter 19 is configured so as to be between a voltage value at the “H” level and “L” level of the 01 alternating data signal output from the alien drivers. This is achieved by configuring the output from the voltage detector 3 to be equivalent to the 01 alternating signal.

Firstly, a voltage value on the “H” level side is detected from the crosstalk of the 01 alternating data signal output from the alien drivers. The level of the setting is increased by one degree so as to increase the voltage output from the D/A converter 19, and the output from the voltage comparator 3 is checked. This process is repeated until the output from the voltage comparator 3 continuously indicates data of “0” for more than 3 bits (i.e., more than 3 clock signal cycles (specified number of cycles)) (it is assumed that “0” is output when the voltage at the D/A converter 19 is greater than the voltage output from the AC-to-DC converter 18 and “1” is output when the voltage at the D/A converter 19 is smaller than the voltage output from the AC-to-DC converter 18). The set value (voltage value) of the D/A converter 19 at the time when the output from the voltage comparator 3 has continuously output “0” for more than 3 bits (i.e., more than 3 clock signal cycles (specified number of cycles)) is recorded in the memory 16.

Next, a voltage value on the “L” level side is detected from the crosstalk of the 01 alternating data signals output from the alien drivers. Then, the level of the setting is reduced by one step so as to decrease the voltage output from the D/A converter 19, and the output from the voltage comparator 3 is checked. This process is repeated until the output from the voltage comparator 3 continuously indicates data of “1” for more than 3 bits (i.e., more than 3 clock signal cycles (specified number of cycles)). The set value (voltage value) of the D/A converter 19 at the time when the output from the voltage comparator 3 has continuously output “1” for more than 3 bits (i.e., more than 3 clock signal cycles (specified number of cycles)) is recorded in the memory 16. Then, the amplitude value of the crosstalk is calculated by subtracting the obtained voltage at the “L” level from a voltage at the “H” level of the crosstalk to obtain. The resultant value is corrected by a correction value for the input amplitude detector, which is obtained by the controller 15 by performing calibration. Then, it is determined whether the detected amount of crosstalk (voltage) meets a standard value, and the resultant data is sent to the test control computer through an external output port.

FIG. 19 is a flowchart of the processes of a check and test where crosstalk is detected to judge the detected crosstalk according to an aimed value or the like. In step S55, the controller 15 turns on the switch 24 according to the mode setting. In step S56, the output from the driver of the alien IC 35 is turned OFF. In step S57, a 01 alternating data signal is output from the alien driver 1 or 2. In step S58, amplitude is detected by the amplitude detector 17. In step S59, a signal is converted to a DC level by an AC-to-DC converter 19. In step S60, a transient voltage is set to the D/A converter 19. Here, the transient voltage is set by using a value obtained in the calibration of the D/A converter 19. In step S61, the voltage comparator 3 compares a voltage output from the D/A converter 19 with a voltage output from the D/A converter 19. In step S62, the controller 15 judges a comparison result of the voltage. In other words, firstly, the voltage at the D/A converter 19 is set such that the output from the voltage comparator 3 will be 01 alternating in step S60 to S62. Next, the voltage at the D/A converter 19 is gradually increased such that the voltage at the D/A converter 19 will be greater than the voltage from the AC-to-DC converter 19 a specified number of times (for example, three times). Then, the voltage at the D/A converter 19 at that time is recorded in the memory 16 as a voltage at the “H” level of the voltage from the AC-to-DC converter 19. Moreover, the voltage at the D/A converter 19 is restored to be an original value and the voltage at the D/A converter 19 is gradually decreased such that the voltage at the D/A converter 19 will be smaller than the voltage from the AC-to-DC converter 19 a specified number of times (for example, three times). Then, the voltage at the D/A converter 19 at that time is recorded in the memory 16 as a voltage at the “L” level of the voltage from the AC-to-DC converter 19. The voltage amplitude of the crosstalk is calculated by subtracting the voltage at the “L” level from the voltage at the “H” level of the crosstalk stored in the memory 16. In step S63, the calculated voltage amplitude of the crosstalk is corrected by the correction value that is obtained in the calibration of the input amplitude detector and is stored in the memory 16 to judge whether or not the corrected voltage amplitude of the crosstalk meets the standards.

If the amount of crosstalk is desired to be equal to or smaller than 50 mV for example, notification that there is no problem is sent to the test control computer when the voltage detected in the detection above (the amount of crosstalk) is 30 mV, and notification that a problem is present is sent to the test control computer when the detected voltage is 80 mV.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention has (have) been described in detail, it should be understood that the various changes, substitutions, and alterations could be made hereto without departing from the spirit and scope of the invention.

What is claimed is:

1. A semiconductor device into which a testing device is integrated, the semiconductor device comprising:
a calibration unit integrated into the semiconductor device and configured to calibrate an element of the testing device; and
a memory integrated into the semiconductor device and configured to store a correction value for a deviation from a reference value of a characteristic of the element obtained as a result of the calibration,
wherein
a result of a test performed by the testing device of the semiconductor device is corrected by the correction value stored in the memory to determine whether the corrected result meets standards.

2. The semiconductor device according to claim 1, further comprising:
a driver configured to output a signal at a specified frequency; and
an input circuit configured to receive an output from the driver as an input,
wherein
the calibration unit includes
an input amplitude detector integrated into the semiconductor device and configured to branch and receive an input to the input circuit and to detect a voltage amplitude of a received signal,
a phase detection circuit integrated into the semiconductor device and configured to branch and receive an output from a receiver of the input circuit, detect a phase value of a received signal, and detect a phase value of a clock signal from an external clock that generates a clock signal having a previously determined phase value and an amount of jitter, and
a controller integrated into the semiconductor device and configured to calculate as an amplitude correction value a difference between voltage amplitude detected by the input amplitude detector and voltage amplitude of an output from the driver, calculate an amount of jitter from the phase value detected by the phase detection circuit, and calculate a difference between the calculated amount of jitter and the previously determined amount of jitter as an amount-of-jitter correction value,
the memory stores the amplitude correction value and the amount-of-jitter correction value, and
a measurement result of amplitude and an amount of jitter of an externally input signal to the semiconductor device is corrected by the amplitude correction value and the amount-of-jitter correction value stored in the memory to determine whether the corrected measurement result meets standards.

3. The semiconductor device according to claim 2, wherein
the driver is a driver of an output circuit used by the semiconductor device to send a signal outside.

4. The semiconductor device according to claim 2, wherein
a difference between a set value and an actual value is measured from a voltage amplitude of an output signal from the driver, and an error is stored in the memory as a driver voltage amplitude correction value, and
voltage amplitude of the driver used for calculating the amplitude correction value is corrected by the driver voltage amplitude correction value to be used for calculating the amplitude correction value.

5. The semiconductor device according to claim 2, wherein
a signal at a specified frequency output from the driver is a 01 alternating signal.

6. The semiconductor device according to claim 2, wherein
the phase detection circuit includes:
a phase clock unit configured to generate a plurality of phase clock signals with a plurality of varying phase differences by a specified unit of phase difference; and
a plurality of phase detectors configured to compare each of the plurality of phase clock signals with an input signal.

7. The semiconductor device according to claim 6, wherein
the plurality of phase clock signals are obtained by sequentially shifting a reference clock, which is output from a PLL circuit integrated into the semiconductor device, by the specified unit of phase difference.

8. The semiconductor device according to claim 6, wherein
the phase detection circuit compares each of the plurality of phase clock signals with an input signal a specified number of times, and
the controller measures an amount of jitter by calculating an average of results of comparison performed the specified number of times.

9. The semiconductor device according to claim 2, wherein
when an input terminal of the input circuit is connected to a wiring board having a plurality of wires, crosstalk interfering with the input circuit from devices other than another semiconductor device to which the input circuit is connected, is measured, and whether an amount of crosstalk meets standards, is tested.

10. A method for controlling a semiconductor device into which a testing device is integrated, the method comprising:
calibrating an element of the testing device by using a calibration unit integrated into the semiconductor device; and
storing a correction value for a deviation from a reference of the element obtained as a result of the calibration value in a memory integrated into the semiconductor device,
wherein
a result of a test performed by the semiconductor device is corrected by the correction value to determine whether the corrected result meets standards.
